(19) United States
(12) Patent Application Publication
(10) Pub. No.: US 2014/0057460 A1
(43) Pub. Date: Feb. 27, 2014

(54) METHODS OF THERMALLY PROCESSING A SUBSTRATE

(71) Applicant: Applied Materials, Inc., Santa Clara, CA (US)

(72) Inventor: Aaron Muir HUNTER, Santa Cruz, CA (US)

(73) Assignee: APPLIED MATERIALS, INC., Santa Clara, CA (US)

(21) Appl. No.: 14/049,752

(22) Filed: Oct. 9, 2013

Related U.S. Application Data
(63) Continuation of application No. 13/553,224, filed on Jul. 19, 2012.

(51) Int. Cl. H01L 21/263; H01L 21/268

(52) U.S. Cl. CPC H01L 21/2636; H01L 21/268
USPC 438/795

(57) ABSTRACT

The present invention generally relates to methods for thermally processing substrates. In one embodiment, a substrate having an amorphous thin film thereon is subjected to a first pulse of electromagnetic energy. The first pulse of electromagnetic energy has a first fluence insufficient to complete the thermal processing. After a predetermined amount of time, the substrate is then subjected to a second pulse of electromagnetic energy having a second fluence greater than the first fluence. The second fluence is generally sufficient to complete the thermal processing. Exposing the substrate to the lower fluence first pulse before the second pulse reduces damage to a thin film disposed on the substrate. In another embodiment, a substrate is exposed to a plurality of electromagnetic energy pulses. The plurality of electromagnetic energy pulses are spaced at increasing intervals to reduce the rate of recrystallization of a film on the substrate, thus increasing the size of the crystals formed during the recrystallization.

### CROSS-REFERENCE TO RELATED APPLICATIONS

This application is a continuation of co-pending U.S. patent application Ser. No. 13/553,224, filed Jul. 19, 2012, which claims benefit of United States provisional patent application Ser. No. 61/513,489, filed Jul. 29, 2011. Each of the aforementioned related patent applications is herein incorporated by reference

### BACKGROUND OF THE INVENTION

1. Field of the Invention

Embodiments of the invention generally relate to methods of thermally processing substrates.

2. Description of the Related Art

Thermal processing plays an important role in the manufacturing of semiconductor devices, most prominently in processes of annealing and dopant activation. Conventionally, substrates have been subjected to processes of furnace annealing, rapid thermal annealing, flash lamp annealing, spike annealing, and laser annealing to reduce supplemental heat history that tends to degrade device properties. As devices grow smaller, and regions that are to be annealed approach 100 angstroms or less in size, further advances are needed to improve dopant activation and crystal defect repair without diffusion of dopants to unwanted locations. Annealing with lasers has developed as a promising method of annealing ever smaller devices. Many substrates, especially silicon, have a temperature dependent absorption profile, absorbing annealing energy more readily at higher temperatures. Thus, at lower temperatures, annealing energy is poorly absorbed, and may result in thermal stresses that can damage substrates.

Therefore, there is a need for thermal processing methods which address the temperature dependence of substrates.

### SUMMARY OF THE INVENTION

The present invention generally relates to methods for thermally processing substrates. In one embodiment, a substrate having an amorphous thin film thereon is subjected to a first pulse of electromagnetic energy. The first pulse of electromagnetic energy has a first fluence insufficient to complete the thermal processing. After a predetermined amount of time, the substrate is then subjected to a second pulse of electromagnetic energy having a second fluence greater than the first fluence. The second fluence is generally sufficient to complete the thermal processing. Exposing the substrate to the lower fluence first pulse before the second pulse reduces damage to a thin film disposed on the substrate. In another embodiment, a substrate is exposed to a plurality of electromagnetic energy pulses. The plurality of electromagnetic energy pulses are spaced at increasing intervals to reduce the rate of recrystallization of a film on the substrate, thus increasing the size of the crystals formed during the recrystallization.

In one embodiment, a method of redistributing dopants within a substrate comprises exposing the substrate having a thin film formed thereon to a first pulse of electromagnetic energy. The first pulse of electromagnetic energy has a first fluence insufficient to complete the thermal processing. The method further comprises exposing the substrate to a second pulse of electromagnetic energy. The second pulse of electromagnetic energy has a second fluence greater than the first fluence.

In another embodiment, a method of thermally processing a substrate sequentially comprises exposing a substrate having a thin film formed thereon to electromagnetic energy to form a molten thin film, and then waiting a first period of time. The molten thin film is then exposed to a first pulse of electromagnetic energy having a first fluence. A second period of time is allowed to elapse, and then the molten thin film is exposed to a second pulse of electromagnetic energy having a second fluence. The molten thin film is then allowed to recrystallize.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic illustration of a thermal processing apparatus according to one embodiment of the invention.

FIG. 2 is a flow diagram of a method of thermally processing a substrate according to one embodiment of the invention.

FIG. 3 is a flow diagram of a method of thermally processing a substrate according to another embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally relates to methods for thermally processing substrates. In one embodiment, a substrate having an amorphous thin film thereon is subjected to a first pulse of electromagnetic energy. The first pulse of electromagnetic energy has a first fluence insufficient to complete the thermal processing. After a predetermined amount of time, the substrate is then subjected to a second pulse of electromagnetic energy having a second fluence greater than the first fluence. The second fluence is generally sufficient to complete the thermal processing. Exposing the substrate to the lower fluence first pulse before the second pulse reduces damage to a thin film disposed on the substrate. In another embodiment, a substrate is exposed to a plurality of electromagnetic energy pulses. The plurality of electromagnetic energy pulses are spaced at increasing intervals to reduce the rate of recrystallization of a film on the substrate, thus increasing the size of the crystals formed during the recrystallization.

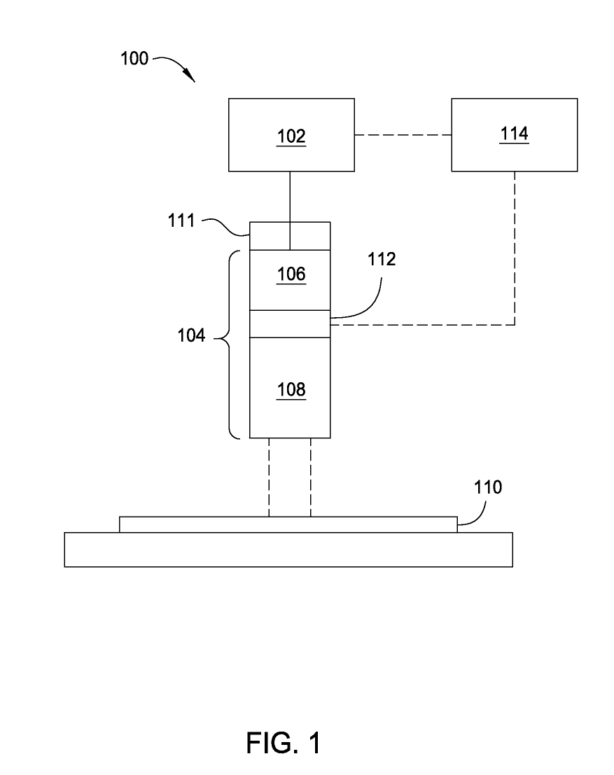

FIG. 1 is a schematic illustration of a thermal processing apparatus 100 according to one embodiment of the invention. The thermal processing apparatus 100 includes a power source 102 coupled to an energy source 104. The energy source 104 includes an energy generator 106, such as a light source, and an optical assembly 108. The energy generator 106 is configured to produce electromagnetic energy and direct the electromagnetic energy into the optical assembly 108. The optical assembly then shapes the electromagnetic energy as desired for delivery to a substrate 110. The optical assembly 108 generally includes lenses, filters, mirrors, and the like that are configured to focus, polarize, de-polarize, filter or adjust coherency of the energy produced by the energy generator 106.

In order to deliver pulses of energy, the energy generator 106 may contain a pulsed laser, which is configurable to emit light at a single wavelength or at two or more wavelengths simultaneously. The energy generator 106 is an Nd:YAG laser, with one or more internal frequency converters. However, other types of laser are contemplated and may be utilized. The energy generator 106 may be configured to emit three or more wavelengths simultaneously, or further, to provide a wavelength-tunable output. In one example, the laser head used in the energy generator 106 is Q-switched to emit short, intense pulses, with pulse duration ranging, for example, from 1 nanosecond to 1 second, such as about 20 nanoseconds to about 30 nanoseconds.

In order to effect a pulsed laser output, the thermal processing apparatus 100 contains a switch 112. The switch 112 may be a fast shutter that can be opened or closed in 1 μsec or less. Alternately, the switch 112 may be an optical switch, such as an opaque crystal that becomes clear in less than 1 μsec, such as less than 1 nanosecond, when light of threshold intensity impinges on it. The switch 112 generates pulses by interrupting a continuous beam of electromagnetic energy directed toward the substrate110. The switch 112 is operated by a controller 114, and is located outside the energy generator 106 and is coupled to an outlet area of the energy generator 106. Alternatively, the switch 112 may be located inside the energy generator 106.

The energy source 104 is generally adapted to deliver electromagnetic energy to preferentially anneal certain desired regions of the substrate 110. Typical sources of electromagnetic energy include, but are not limited to, an optical radiation source (e.g., laser or flash lamps), an electron beam source, an ion beam source, and/or a microwave energy source. When utilizing a laser, the energy source 104 may be adapted to deliver electromagnetic radiation at a wavelength between about 500 nanometers and about 11 micrometers at a fluence (i.e., energy per unit area of substrate) within a range of about 1×10⁷ watts per cubic centimeter to about 1×10⁹ watts per cubic centimeter. In one aspect, the substrate 110 is exposed to multiple pulses of energy from a laser that emits radiation at one or more appropriate wavelengths for a desired period of time. The wavelength(s) of the energy source 104 may be tuned so that a significant portion of the emitted electromagnetic radiation is absorbed by the substrate 110, or by a layer disposed thereon, such as an amorphous silicon thin film.

The controller 114 is generally designed to facilitate the control and automation of the thermal processing techniques described herein and typically may include a central processing unit, memory, and support circuits. The central processing unit may be one of any form of computer processors that are used in industrial settings for controlling various processes and hardware (e.g., conventional electromagnetic radiation detectors, motors, or laser hardware). The memory is connected to the central processing unit and may be one or more of a readily available memory, such as random access memory, read only memory, floppy disk, hard disk, or any other form of digital storage, local or remote. Software instructions and data can be coded and stored within the memory for instructing the central processing unit. A program (or computer instructions) readable by the controller 114 determines which tasks are performable on a substrate. For example, a program may be stored on the controller 114 to execute methods described herein.

Although FIG. 1 depicts one embodiment of a thermal processing apparatus 100, other embodiments are also contemplated. In an alternative embodiment, the energy generator 106 may be switched by electrical means. For example, the controller 114 may be configured to switch the power source 102 on and off as needed. Alternatively, a capacitor 111 may be provided such that the capacitor 111 is charged by the power source 102 and discharged into the energy generator 106 by virtue of circuitry energized by the controller 114. In embodiments where the switch 112 is an electrical switch, the electrical switch may be configured to switch power on or off in less than about 1 nanosecond.

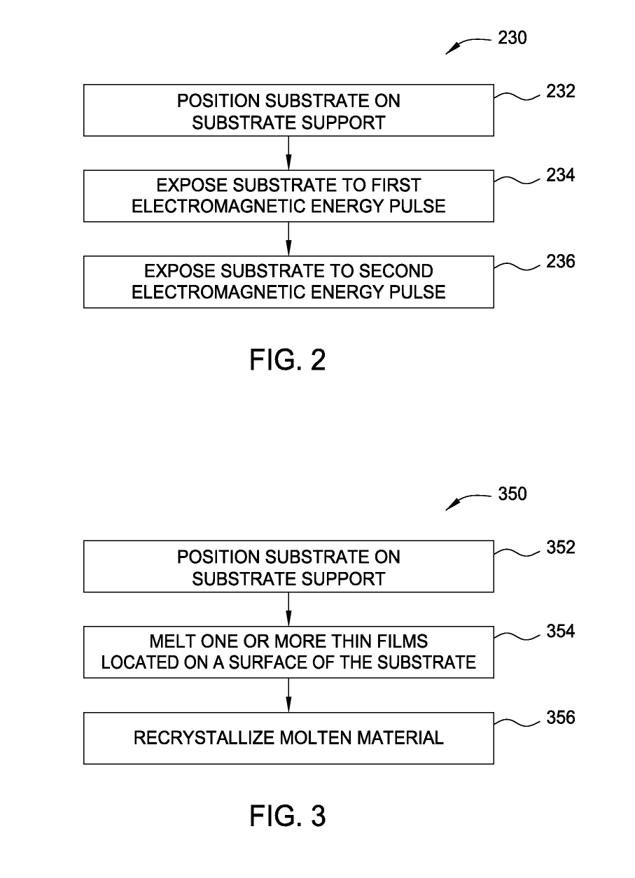

FIG. 2 is a flow diagram 230 of a method of thermally processing a substrate according to one embodiment of the invention. For example, flow diagram 230 may be a method of activating dopants within a substrate, and, in such a process, the treated substrate and films formed thereon generally remain in a solid state and are not melted. Flow diagram 230 begins at operation 232 in which a substrate, such as a monocrystalline silicon substrate having one or more silicon thin films disposed thereon, is positioned on a substrate support adjacent to an energy source. In operation 234, an area of the substrate surface is exposed to a first pulse of electromagnetic energy from an energy source. The first pulse of electromagnetic energy generally has a first fluence insufficient to complete the thermal processing (e.g., activation of dopants) of the substrate. The first pulse of electromagnetic radiation delivered to the substrate surface in operation 234 may be a combination of up to four energy sources, such as lasers, which may have different or the same fluence, wavelength, pulse shape, or exposure times. The first pulse is intended to reduce the thermal shock to layers disposed on the substrate when subjecting the substrate to a second electromagnetic energy pulse (i.e., operation 236) which has sufficient energy to complete the thermal processing of the substrate.

In operation 236, after a predetermined amount of time, the substrate is exposed to a second electromagnetic energy pulse from the energy source. Preferably, the second pulse of electromagnetic energy does not temporally overlap with the first pulse of electromagnetic radiation, and may be spaced apart from the first pulse of electromagnetic radiation by about 1 nanosecond to several seconds, for example, about 1 to about 3 microseconds. The second electromagnetic energy pulse generally covers the same area of the substrate as the first electromagnetic energy pulse; however, the second electromagnetic energy pulse has a greater fluence than the first electromagnetic energy pulse. The second electromagnetic energy pulse generally has a great enough fluence to complete the thermal processing of the radiated area of the substrate. Because the substrate has been previously exposed to a first pulse of electromagnetic radiation, the thin films disposed on the surface of the substrate experience reduced peeling, flaking, cracking, or ablation which would otherwise be caused by the high fluence of the second electromagnetic energy pulse. Similar to the first pulse of electromagnetic radiation, the second pulse of electromagnetic radiation may be a combination of up to four energy sources, such as lasers, which may have different or the same fluence, wavelength, pulse shape, or exposure times.

It is believed that the application of the first pulse of electromagnetic energy modifies or changes one or more properties of the thin films disposed on the substrate, or the substrate itself, in order to make the thin film or substrate more receptive to a second pulse. For example, it is believed that the first pulse modifies the adherence of the thin film to the substrate (or other thin films) so that the substrate does not delaminate when subjected to a second pulse of electromagnetic energy having a higher fluence, which would otherwise by itself cause delamination or flaking of the thin film. Alternatively, the application of the first pulse may alter the thermal properties of the thin film, such as the coefficient of thermal expansion, such that likelihood of delamination upon exposure to the second pulse is reduced. It is further believed that since the first pulse modifies the adherence or the thermal properties of the thin film, the likelihood of delamination of the thin film remains reduced even after the energy of the first pulse has dissipated from the thin film. Thus, in order to achieve the benefits described above, the second pulse need not be temporally spaced so closely to the first pulse that the radiated area of the thin film still experiences an elevated temperature caused by the first pulse.

In another aspect, the first pulse may be a “glue” pulse which increases the strength of the substrate or the thin films disposed therein such that the substrate or the thin films are able to withstand the stresses of the higher fluence second pulse. In another aspect, the first pulse may increase the absorptivity of the substrate or the thin films thereon to increase the effect of the second pulse. In such an embodiment, the second pulse may be more intense or less intense than the first pulse.

Flow diagram 230 illustrates one method for thermally processing a substrate; however, other embodiments are also contemplated. In another embodiment, more than two electromagnetic pulses may be applied to the surface of a substrate during a thermal process. In such an embodiment, each successive pulse may have increased fluence compared to the prior pulse until thermal processing of the substrate is complete. In yet another embodiment, the flow diagram 230 may be applied to thermal processes in which the radiated portion of the substrate is melted, and then recrystallized. In such an embodiment, the first pulse generally does not have sufficient fluence to complete the thermal processing (e.g., melting) of the material located on the substrate surface. Rather, the first pulse applies a first amount of energy to the substrate surface to reduce the probability of ablation, while the second or subsequent pulses complete the thermal processing. In one embodiment of flow diagram 230, the fluence of the first pulse may be about 25 percent to about 75 percent of the fluence of the second pulse. In yet another embodiment, it is contemplated that the first fluence may be greater than the second fluence. For example, if the first pulse increases absorptivity of the substrate, a lower intensity second pulse may complete the thermal processing due to the increased absorption caused by the first pulse.

FIG. 3 is a flow diagram 350 of a method of thermally processing a substrate according to another embodiment of the invention. Flow diagram 350 begins at operation 352. In operation 352, a substrate, such as a monocrystalline silicon substrate having one or more silicon thin films disposed thereon, is positioned on a substrate support adjacent to an energy source. In operation 354, the energy source applies a sufficient amount of energy to the surface of the substrate to melt one or more thin films disposed thereon. It is to be noted that the embodiment discussed in reference to flow diagram 230 may be utilized to melt the thin film located on the surface of the substrate. Additionally, it should be noted that the amount of energy applied to melt the films located on the substrate may be supplied in one or more pulses.

In operation 356, the molten thin film is allowed to recrystallize. During recrystallization, the molten material utilizes the crystal lattice of the underlying substrate as a template during solidification, thus assuming the same crystalline structure as the underlying substrate. In order to effect the growth of larger crystals in operation 356, the rate of recrystallization is reduced by inputting additional energy into the molten material. Thus, as some energy dissipates from the molten film during recrystallization, additional energy (but generally less than that which has dissipated) is input back into the molten film by an energy source. Therefore, the amount of time required for the material to recrystallize may be extended an additional 25 percent to 50 percent or more. The additional energy is supplied to the molten material in one or more pulses of electromagnetic energy from the energy source. When inputting energy using a plurality of electromagnetic pulses, the plurality of electromagnetic pulses may be supplied using separate sources, for example, individual lasers. Generally, the plurality of electromagnetic pulses do not temporally overlap with one another. Additionally, in order to further reduce the rate of recrystallization (thus desirably forming larger crystals), the interval between each of the plurality of pulses may be increased, thus reducing the frequency at which the pulses are supplied to the molten material.

Flow diagram 350 illustrates one embodiment for thermally processing a substrate; however, other embodiments are also contemplated. In another embodiment, the rate of recrystallization in operation 356 may be reduced by varying the wavelength, fluence, or exposure time of the plurality of pulses, in addition to or as an alternative to increasing the interval between the pulses. In yet another embodiment, it is contemplated that only some of the intervals between the pulses may be increased, while other intervals remain constant.

In one example, an energy source having four separate lasers is used to melt and recrystallize a thin film on a surface of a substrate. A first laser delivers a first pulse of energy to the surface of a substrate. Generally, the first pulse does not melt the thin film; however, it is contemplated that in some embodiments the first pulse may melt the thin film. After about 20 nanoseconds to about 40 nanoseconds, a second pulse of electromagnetic energy from a second laser is delivered to the surface of the substrate to melt the thin film on the surface of the substrate.

As energy dissipates from the molten material located on the substrate surface, the molten material begins to recrystallize while utilizing the underlying substrate as a lattice template. However, if the material cools too quickly, the material will solidify without achieving the desired level of crystalline growth. Thus, it is desirable to input additional energy into the molten material to control or slow the rate of recrystallization to obtain the desired crystalline growth of the material. In the above example, after completion of the second pulse, the energy from the molten material is allowed to dissipate for about 1 microsecond before a third pulse of energy is delivered to the molten material. Generally, the third pulse has a lower fluence than the second pulse. The additional energy supplied by the third pulse extends the amount of time required for the molten material to recrystallize, since the additional energy supplied by the third pulse must also dissipate. Following application of the third pulse of energy to the substrate surface and a 1 microsecond interval, a fourth pulse of electromagnetic energy is applied to the substrate surface. The fourth pulse may have the same or a lesser fluence than the third pulse.

While the above example illustrates one method of a recrystallizing a substrate, the above example is in no way intended to be limiting regarding the number of pulses or the intervals therebetween when recrystallizing substrates. It should further be noted that the above described embodiments are particularly beneficial when utilized to melt and recrystallize a film horizontally across a surface of a substrate, as well vertically through the depth of a substrate. One example of horizontal growth may include etching a trench in crystalline substrate, and filling the trench with amorphous material. The amorphous material can then be melted and permitted to recrystallized as described above, utilizing the sidewalls of the trench as a template for crystalline growth.

Benefits of the present invention include embodiments for thermally annealing substrates which reduce the occurrence of film cracking, flaking, and delaminating during thermal processing. The application of a first pulse of electromagnetic energy having a lower fluence than is required to complete thermal processing prepares the substrate for a subsequent application of electromagnetic energy. The second application of electromagnetic energy can then complete the thermal processing while having a reduced risk of damaging the substrate. Benefits of the present invention further include methods for growing larger crystalline structures from solidifying molten material. By inputting additional energy into the molten material at increasing intervals, the rate of regrowth is reduced, allowing crystal size to be increased.

While the foregoing is directed to embodiments of the present invention, other and further embodiments of the invention may be devised without departing from the basic scope thereof, and the scope thereof is determined by the claims that follow.

We claim:

1. A method of redistributing dopants within a substrate, comprising:
exposing a region of the substrate having a thin film formed thereon to a first pulse of electromagnetic energy, the first pulse of electromagnetic energy having a first fluence insufficient to complete the thermal processing; and
exposing the region of the substrate to a second pulse of electromagnetic energy, the second pulse of electromagnetic energy having a second fluence greater than the first fluence, wherein the thin film remains in a solid state while redistributing dopants within the substrate.

2. The method of claim 1, further comprising waiting a predetermined amount of time between the completion of the first pulse and the beginning of the second pulse.

3. The method of claim 1, wherein the second pulse of electromagnetic radiation completes the thermal processing.

4. The method of claim 1, wherein the first fluence is about 25 percent to about 75 percent of the second fluence.

5. The method of claim 1, wherein the first pulse of electromagnetic energy and the second pulse of electromagnetic energy each have a wavelength between about 500 nanometers and about 11 micrometers.

6. The method of claim 1, wherein the first pulse of electromagnetic energy and the second pulse of electromagnetic energy each have a length of about 20 nanoseconds to about 30 nanoseconds.

7. The method of claim 1, wherein the first pulse of electromagnetic energy and the second pulse of electromagnetic energy are each generated using a q-switched laser.

8. The method of claim 1, wherein the first pulse of electromagnetic energy and the second pulse of electromagnetic energy are each generated using four energy sources.

9. A method of thermally processing a substrate, sequentially comprising:
exposing a region of a substrate having a thin film formed thereon to electromagnetic energy to form a molten thin film; and
allowing the molten thin film to recrystallize, wherein during the recrystallization, the molten thin film is exposed to a plurality of electromagnetic energy pulses separated by intervals of time, and each interval of time is greater than a previous interval of time in order to extend the recrystallization time of the molten thin film, wherein:
the exposing a substrate comprises exposing the substrate to electromagnetic energy from a first laser; and
the plurality of pulses are provided by at least a second laser.
